(19) United States
(12) Patent Application Publication
(10) Pub. No.: US 2010/0018584 A1
(43) Pub. Date: Jan. 28, 2010

(54) Microfluidic system and method for manufacturing the same

(75) Inventors: Avishay Bransky, Tivon (IL); Korin Natanel, Beer-Sheva (IL); Shulamit Levenberg, Moreshet (IL)

Correspondence Address: MARTIN D. MOYNIHAN d/b/a PRTSI, INC., P.O. BOX 16446, ARLINGTON, VA, 22215, US

(73) Assignee: Technion Research & Development Foundation Ltd., Haifa (IL)

(21) Appl. No.: 12/453,711

(22) Filed: May 20, 2009

Related U.S. Application Data
(60) Provisional application No. 61/084,089, filed on Jul. 28, 2008.
(60) Provisional application No. 61/090,697, filed on Aug. 21, 2008.

(51) Int. Cl. G05D 7/06; B81B 7/02; F15C 3/00; F15C 5/00

(52) U.S. Cl. 137/2; 137/3; 137/831; 29/428

(57) ABSTRACT

A microfluidic system is disclosed. The microfluidic system comprises a microchannel having in fluid communication with a fluid inlet for receiving a first fluid. The microfluidic system can further comprise a piezoelectric actuator which controls the flow of the first fluid in the microchannel by selectively applying external pressure on the wall of the microchannel.

### RELATED APPLICATIONS

This application claims the benefit of priority from U.S. Provisional Patent Application No. 61/084,089 filed Jul. 28, 2008, and 61/090,697, filed Aug. 21, 2008, the contents of which are hereby incorporated by reference.

### FIELD AND BACKGROUND OF THE INVENTION

The present invention, in some embodiments thereof, relates to microfluidics and, more particularly, but not exclusively, to a microfluidic system having an actuator.

Much industrial and academic effort is presently directed at the development of integrated micro devices or systems combining electrical, mechanical and/or optical/electrooptical components, commonly known as Micro Electro Mechanical Systems (MEMS). MEMS are fabricated using integrated circuit batch processing techniques and can range in size from micrometers to millimeters. These systems can sense, control and actuate on the micro scale, and function individually or in arrays to generate effects on the macro scale. MEMS include numerous applications, such as airbag accelerometers, ink-jet heads, radio frequency micro-switches for wireless communications, micro-gyroscopes, digital micro-mirror displays, pico-satellites and the like.

The advantage of MEMS is widely accepted, since mechanics provides superior functionality and is not subject to undesirable electronic noise. In the most general form, MEMS consist of mechanical microstructures, microsensors, microactuators and electronics integrated in the same environment (e.g., on a silicon chip). The microfabrication technology enables fabrication of large arrays of devices, which individually perform simple tasks but in combination can accomplish complicated functions. For example, MEMS for guidance, navigation, motion control and high resolution flow visualization can provide experimental evidence about small-scale phenomena and thus verify fundamental principles in the microcosm.

One type of MEMS is a microfluidic device. Microfluidic devices include components such as channels, reservoirs, mixers, pumps, valves, chambers, cavities, reaction chambers, heaters, fluidic interconnects, diffusers, nozzles, and other microfluidic components. These microfluidic components typically have dimensions between a few micrometers and a few hundreds of micrometers. The small dimensions of the components minimize the physical size, the power consumption, the response time and the waste of the entire system. Such systems may provide wearable miniature devices located either outside or inside the human body.

Applications for microfluidic devices include genetic, chemical, biochemical, pharmaceutical, biomedical, chromatography, integrated circuit cooling, ink-jet printing, medical, radiological and environmental applications.

Microfluidic devices presently occupy an increasingly significant position in chemical and biochemical sensing, molecular separations, drug delivery and other forefront technologies. In a manner similar to that for microelectronics, microfluidic technologies enable the fabrication of highly integrated devices applicable to high throughput, low volume, automatable chemical and biochemical analyses and syntheses. Common fluids used in microfluidic devices include whole blood samples, bacterial cell suspensions, protein or antibody or nucleic acid solutions and various buffers.

The development of miniaturized devices for chemical analysis and for synthesis and fluid manipulation is motivated by the prospects of improved efficiency, reduced cost and enhanced accuracy. Efficient, reliable manufacturing processes are a critical requirement for the cost-effective, high-volume production of devices that are targeted at high-volume, high-throughput test markets. In this respect, microfluidic devices are related to separation of components of a complex mixture for the purpose of analyzing the components individually without interference.

Droplet microfluidics refers to the set of technologies that are being developed for manipulating and monitoring very small, substantially uniform, liquid drops, micro- to femto-liters in volume, which are supported on a solid surface, sandwiched between two solid plates, sucked into a solid channel and/or encapsulated in an immiscible carrier fluid. The manipulations include moving the droplets around, making them coalesce, and breaking them up.

These technologies have a promising potential for developing commercially viable droplet-based microfluidic platforms for biotechnology and other applications. The reason is that in pharmaceutical and bioanalysis applications, enormous savings can be realized by reducing the required amounts of expensive reagents to nano-, pico- and even femto-liter volumes. Additionally, droplet microfluidics technique prevents the contamination of fluid capsules by adsorption or diffusion and facilitates the mixing of reagents even though the characteristic Reynold's numbers are low. Moreover, the smaller the length scale over which transport processes (convection, diffusion and reaction) take place, the faster the completion time of the process. As such, droplet microfluidics is applicable in many applications including high-throughput screening, single-cell analysis and encapsulation, protein crystallization, polymer/gel particles synthesis, vesicule production and chemical micro-reactors.

Many types of droplet microfluidic devices incorporate flows of two immiscible fluids intersecting at a junction. One flow is a continuous flow typically of an oily substance, and another flow is a segmented flow, typically of aqueous substance. At the intersection junction, the continuous phase shears the dispersed phase into ordered uniform droplets.

Known in the art are droplet microfluidic configuration: T-junction configurations [Garstecki et al., Lab Chip, 2006, 6, 437-446; Thorsen et al., Phys. Rev. Lett., 2001, 86, 4163] and cross-junction or flow-focusing configurations [Piotr et al., Appl. Phys. Lett., 2004, 85, 2649-2651; Ward et al., 2005, 26, 3716-3724]. In T-junction configurations, the dispersed phase and the continuous phase are injected from two branches of the junction. Droplets of the dispersed phase are produced as a result of the shear force and interfacial tension at the fluid-fluid interface. In cross-junction configurations, the continuous phase is injected through two outside channels and the dispersed phase is injected through a central channel into a narrow orifice.

Known in the art are several techniques for controlling the generation of droplets. Representative examples include, varying the inlet pressure, dictating a constant flow rate using a pump, electronic control, thermal control and application of high electric field (to this end see, M. Prakash and N. Gershenfeld, Science, 2007, 315, 832-835; Nguyen et al., Appl. Phys. Lett., 2007, 91, 084102; Link et al., Angew. Chem., 2006, 45, 2556-2560; and Mingyan et al., Appl. Phys. Lett., 2005, 87, 031916).

Additional background art includes Tan et al., “Controlled Microfluidic Encapsulation of Cells, Proteins, and Microbeads in Lipid Vesicles,” J. AM. CHEM. SOC. 2006, 128, 5656-5658; Song et al., “Reactions in Droplets in Microfluidic Channels,” Angew. Chem. Int. Ed. 2006, 45, 7336-7356; Stachowiak et al., “Unilamellar vesicle formation and encapsulation by microfluidic jetting,” PNAS, 2008, vol. 105, no. 12, 4697; and Tan et al., “Monodisperse Alginate Hydrogel Microbeads for Cell Encapsulation,” Adv. Mater. 2007, 19, 2696-2701.

### SUMMARY OF THE INVENTION

According to an aspect of some embodiments of the present invention there is provided a microfluidic system. The microfluidic system comprises: an elastic microchannel having an elastic wall and being in fluid communication with a fluid inlet configured for receiving a first fluid; and a piezoelectric actuator configured for controlling flow of the first fluid in the microchannel by selectively applying external pressure on the elastic wall.

According to some embodiments of the invention the system further comprises a controller configured for activating and deactivating the actuator.

According to some embodiments of the invention the system further comprises a flexible membrane adjacent to the elastic wall, the membrane being constituted to transmit displacements induced by the actuator to the elastic wall.

According to some embodiments of the invention the system further comprises at least one additional microchannel being in fluid communication with the elastic microchannel.

According to some embodiments of the invention the at least one additional microchannel intersects with the elastic microchannel.

According to some embodiments of the invention the elastic microchannel branches from the at least one additional microchannel.

According to some embodiments of the invention the at least one additional microchannel is configured for receiving a second fluid through a second inlet, the first and the second fluids being mutually immiscible.

According to some embodiments of the invention the at least one additional microchannel comprises a main microchannel and a branch microchannel, and wherein the elastic microchannel branches from the main microchannel generally opposite to the branch microchannel but offset with respect thereto, such that application of the pressure on the elastic microchannel results in increased fluid flow in the branch microchannel.

According to some embodiments of the invention a resistance to flow characterizing the main microchannel is lower than a resistance to flow characterizing the branch microchannel.

According to some embodiments of the invention the system further comprises an imaging system configured for imaging the microchannel and the fluid; wherein the controller is configured for processing images generated by the imaging system and activating and deactivating the actuator based on, and synchronously with, the processing.

According to some embodiments of the invention the actuator is controlled so as to isolate objects flowing with the first fluid.

According to some embodiments of the invention the actuator is controlled so as to sort objects flowing with the first fluid.

According to some embodiments of the invention the actuator is controlled so as to form droplets of the first fluid in the second fluid.

According to some embodiments of the invention the actuator is controlled so as to encapsulate objects flowing with the first fluid within the second fluid.

According to some embodiments of the invention the actuator is controlled so as to produce a pulsed microfluidic jet.

According to an aspect of some embodiments of the present invention there is provided a microfluidic system. The microfluidic system comprises: a first microfluidic droplet generator and a second microfluidic droplet generator configured for generating fluid droplets in a main microchannel being in fluid communication with the droplet generators; and a plurality of droplet merging chambers branched from the main microchannel and configured to impose a velocity gradient on droplets flowing in the droplet merging chambers, such that at least two droplets collide and coalescent to a larger droplet within at least one of the droplet merging chambers.

According to some embodiments of the invention the system further comprises a plurality of mixing chambers respectively connected to the droplet merging chambers and constituted for reducing the velocity of droplets exiting the droplet merging chambers and flowing within the mixing chambers.

According to some embodiments of the invention the droplet merging chambers branch from the main microchannel in a comb-like arrangement.

According to some embodiments of the invention the system further comprises a collection microchannel in fluid communication with the droplet merging chambers, for collecting the larger droplets.

According to some embodiments of the invention the system further comprises an inspection zone, being in fluid communication with the collection microchannels.

According to some embodiments of the invention the inspection zone is in a form of a comb-like arrangement of microchannels.

According to some embodiments of the invention the system further comprises a detector for detecting the larger droplets.

According to an aspect of some embodiments of the present invention there is provided a method which comprises introducing a first fluid into an inlet of an elastic microchannel having an elastic wall, and selectively applying external pressure on a wall of the microchannel so as to control the flow of the first fluid in the microchannel.

According to some embodiments of the invention the external pressure is applied via a flexible membrane adjacent to the elastic wall.

According to some embodiments of the invention the method further comprises introducing a second fluid to at least one additional microchannel being in fluid communication with the elastic microchannel.

According to some embodiments of the invention the at least one additional microchannel comprises a main microchannel and a branch microchannel, wherein the elastic microchannel branches from the main microchannel generally opposite to the branch microchannel but offset with respect thereto, and wherein the application of the pressure is executed so as to increase fluid flow in the branch microchannel.

According to some embodiments of the invention the method further comprises: imaging the microchannel and the fluid; and processing images generated by the imaging method; wherein the application of pressure is based on, and synchronously with, the processing.

According to some embodiments of the invention the application of pressure is executed so as to isolate objects flowing with the first fluid.

According to some embodiments of the invention the application of pressure is executed so as to sort objects flowing with the first fluid.

According to some embodiments of the invention the application of pressure is executed so as to form droplets of the first fluid in the second fluid.

According to some embodiments of the invention a size dispersion of the droplets is characterized by a standard deviation of less than 1%.

According to some embodiments of the invention the application of pressure is executed so as to encapsulate objects flowing with the first fluid within the second fluid.

According to some embodiments of the invention the application of pressure is executed so as to produce a pulsed microfluidic jet.

According to an aspect of some embodiments of the present invention there is provided a method of manufacturing a microfluidic system. The method comprises forming an elastic microchannel in a substrate, and attaching a piezoelectric actuator adjacently to the microchannel such as to allow the actuator to apply external pressure on an elastic wall of the microchannel.

According to some embodiments of the invention the method further comprises forming a membrane adjacently to the elastic wall, the membrane being constituted to transmit displacement induced by the actuator to the elastic wall.

According to some embodiments of the invention the substrate is made of an elastomer.

According to some embodiments of the invention the elastic microchannel is formed by employing at least one technique selected from the group consisting of soft lithography, hot embossing, stereolithography, three-dimensional jet printing, dry etching and injection molding.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE DRAWINGS

Some embodiments of the invention are herein described, by way of example only, with reference to the accompanying drawings and images. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic illustration of a side view of a microfluidic system, according to various exemplary embodiments of the present invention.

FIGS. 2A and 2B are schematic illustrations of representative examples of a cross-junction configuration (FIG. 2A) and a T-junction configuration (FIG. 2B), according to various exemplary embodiments of the present invention.

FIG. 3 is a schematic illustration of a top view of the system in embodiments in which the system is used for sorting or isolation of objects.

FIG. 4 is a flowchart diagram of a method suitable for manipulating fluid and/or object suspended in fluid according to various exemplary embodiments of the present invention;

FIG. 5 is a flowchart diagram of a method suitable for manufacturing a microfluidic system according to various exemplary embodiments of the present invention.

FIG. 6 is a schematic illustration of a production procedure of a prototype microfluidic system, manufactured according to various exemplary embodiments of the present invention.

FIG. 7A is an image of a typical droplet formed according to various exemplary embodiments of the present invention.

FIG. 7B shows the droplet of FIG. 7A after segmentation, performed according to various exemplary embodiments of the present invention.

FIG. 7C illustrates a cross section of a droplet when constrained by a microchannel of height h.

FIG. 8 illustrates the location of water vertex inside the nozzle as determined from the equilibrium between hydrostatic pressure and interfacial tension. As the nozzle slanting angle α increases, the vertical location of the vertex (y) is less sensitive to changes in pressure.

FIGS. 9A-B are microscope images of a cross flow configuration (FIG. 9A) and a T configuration (FIG. 9B) having an orifice width to main channel width ratio of 1/2, as manufactured and operated according to various exemplary embodiments of the present invention. The images demonstrate that the water vertex returns to its equilibrium state after droplet formation.

FIG. 10 shows the distribution of two typical droplet diameters obtained according to various exemplary embodiments of the present invention using a T-junction configuration with a voltage pulse of 20 ms and amplitudes of 90 V and 50V. The present embodiments are capable of producing highly uniformed droplets with a deviation of less than 0.3%.

FIGS. 11A and 11B are microscope images demonstrating the size and shape uniformity of droplets generated according to various exemplary embodiments of the present invention.

FIG. 12 shows a calculated mean droplet volume as a function of the amplitude of the voltage applied to the actuator, in a T-junction microfluidic system manufactured and operated according to various exemplary embodiments of the present invention using a 15 ms pulse.

FIG. 13 is a graph showing the mean droplet diameter as a function of the pulse duration as obtained in a T-junction microfluidic system manufactured and operated according to various exemplary embodiments of the present invention using voltage amplitudes of 60 V and 120 V.

FIGS. 14A and 14B are schematic illustrations of microchannel configuration of a prototype microfluidic system, manufactured and operated according to various exemplary embodiments of the present invention.

FIGS. 15A and 15B show the results of a finite element simulation performed according to various exemplary embodiments of the present invention so as to analyze flow within the microchannels of the prototype system schematically illustrated in FIGS. 14A and 14B.

FIGS. 16A-D are images of the prototype system which is schematically illustrated in FIGS. 14A and 14B. The images show four stages of a sorting procedure performed according to various exemplary embodiments of the present invention.

FIGS. 17A and 17B are schematic illustrations of top views of a microfluidic system in embodiments in which a network of microchannels is employed for multiple droplet coalescence.

FIGS. 18A-C are images of a prototype microfluidic system, manufactured and operated according to various exemplary embodiments of the present invention for coalescing droplets.

### DESCRIPTION OF SPECIFIC EMBODIMENTS OF THE INVENTION

The present invention, in some embodiments thereof, relates to microfluidics and, more particularly, but not exclusively, to a microfluidic system having an actuator.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

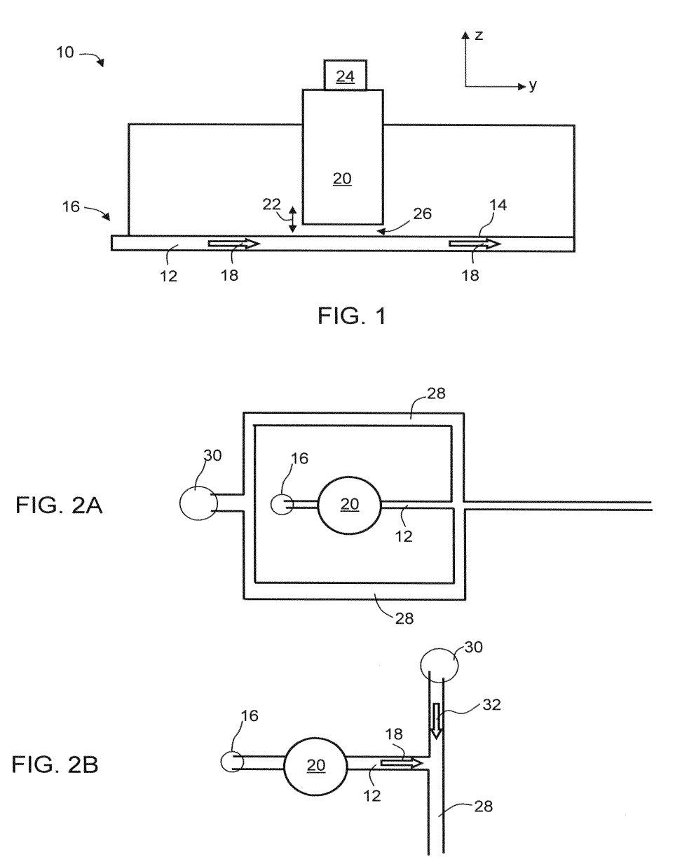

Referring now to the drawings, FIG. 1 illustrates a side view of a microfluidic system 10, according to various exemplary embodiments of the present invention.

The term “microfluidic system” as used herein refers to a system having one or more fluid microchannels.

The term “microchannel” as used herein refers to a fluid channel having cross-sectional dimensions the largest of which being less than 1 mm, more preferably less than 500 μm, more preferably less than 400 μm, more preferably less than 300 μm, more preferably less than 200 μm, e.g., 100 μm or smaller.

System 10 can be used for manipulating fluid and/or objects such as droplets, bubbles, capsules, particles, cells and the like. Representative and non-limiting list of fluid media and objects which can be manipulated in accordance with various embodiments of the present invention is provided hereinunder.

System 10 comprises an elastic microchannel 12 having an elastic wall 14 and being in fluid communication with a fluid inlet 16 configured for receiving a first fluid medium 18. Fluid medium 18 is represented in FIG. 1 by a block arrow.

System 10 further comprises a piezoelectric actuator 20 configured for controlling flow of first fluid 18 in microchannel 12 by selectively applying external pressure on elastic wall 14. Actuator 20 can be stack actuator formed of several layers of piezoelectric material. A representative example of a piezoelectric actuator suitable for the present embodiments is a bending disk piezoelectric actuator, such as, but not limited to, the T216-A4NO-073X, distributed by Piezo systems inc. USA.

The piezoelectric actuator translates electric voltage to displacements. In various exemplary embodiments of the invention the displacements are in the nanometer scale at rates in the MHz range. Upon application of an electric field in the thickness direction (the z direction in FIG. 1) a displacement 22 occurs in actuator 20 also in the thickness direction. A displacement directed toward wall 14 results in a mechanical bias in the form of external pressure applied to wall 14 such that the pressure of fluid 18 within microchannel 12 is increased. A displacement directed away from wall 14 releases the bias and reduces the pressure of fluid 18 within microchannel 12. The changes in fluid pressure induce flow changes within microchannel 12. Thus, actuator 20 controls the flow within microchannel 12.

The amount of displacement (stroke) of actuator 20 is preferably within the elasticity range of wall 14. In other words, once the bias is released, wall 14 restores its original shape. The activation and deactivation of actuator 20 thus controls the flow within microchannel 12. The displacements of actuator 20 can be transmitted to wall 14 directly, or, more preferably, via a flexible and elastic membrane 26 adjacent to wall 14.

In some embodiments of the present invention system 10 comprises a controller 24 which activates and deactivates actuator 20, according to the desired flow scheme.

Although system 20 is shown as having a single microchannel and a single actuator, this need not necessarily be the case, since in some applications system 10 may comprise more than one microchannel and/or more than one actuator. When system 10 comprises more When system 10 comprises more than one microchannel, two or more of the microchannels are preferably in fluid communication thereamongst. For example, system 10 can comprise a network of microchannels in which the flow is controlled by one or more piezoelectric actuators which are activated and deactivated (e.g., by means of controller 24) according to the desired flow scheme within the network.

Before providing a further detailed description of the microfluidic system as delineated hereinabove and in accordance with some embodiments of the present invention, attention will be given to the advantages and potential applications offered thereby.

It was found by the present Inventors that microfluidic system 10 can be a droplet microfluidic system, e.g., for generating droplets of one fluid within another fluid serving as a carrier for the droplets.

Unless otherwise defined, the term “fluid droplet” encompasses liquid droplet as well as gas bubble.

In traditional microfluidic systems, the size of the droplets, the formation rate of the droplets, the distance between the droplets and the velocity of the droplets within the microchannel cannot be individually controlled since some of these quantities are correlated while other are anticorrelated. For example, in traditional microfluidic systems, as the ratio between the dispersed flow and the continuous flow rises, the droplet diameter, generation frequency and velocity increase, but the distance between droplets decreases, and it is not possible to individually control these quantities for two reasons. Firstly, in traditional pressure driven microfluidic systems, there is a minimal pressure which required for overcoming the surface tension to initiate droplet generation. Thus, it is impossible to generate droplets in a large range of low flow rates. Secondly, when the dispersed flow to continuous flow ratio is small the size of the droplet is governed by the geometry and scale of the orifice.

One advantage of the droplet microfluidic system of the present embodiments is that any of the parameters governing the droplet microfluidics, particularly the size of the droplets, the formation rate of the droplets, the distance between the droplets and the velocity of the droplets within the microchannel, can be individually controlled.

Another advantage of the droplet microfluidic system of the present embodiments is that it is capable of generating a plurality of droplets of substantially uniform size and shape. In various exemplary embodiments of the invention the size dispersion of the droplets produced by the microfluidic system produces is characterized by a standard deviation of less than 1%, more preferably less than 0.8%, more preferably less than 0.6%, more preferably less than 0.4%, more preferably less than 0.3%, more preferably less than 0.2%, e.g., 0.1% or less.

This is advantageous over traditional pressure driven droplet microfluidic systems, in which there is a droplet non-uniformity and instability. In such systems, if the flow rate of the water is too high, a longer jet of fluid passes through the orifice and breaks up downstream into less uniform droplets. On the other hand, if the flow rate of the water is too low, the droplet breakup in the orifice becomes irregular again, which produces a wider range of droplet sizes. Furthermore, droplet formation depends on the pressure drop across the water/oil interface. This pressure changes according to the number of droplets present downstream increasing the resistance to flow. Thus variation in droplets flow may affect droplet generation in an unexpected fashion.

While some of the embodiments herein are described with a particular emphasis to droplet microfluidic systems, it is to be understood that more detailed reference to droplet microfluidic systems is not to be interpreted as limiting the scope of the invention in any way. Thus, the microfluidic system of the present embodiments can be utilized in droplet microfluidics as well as other types of microfluidics (e.g., continuous-flow microfluidics).

Generally, the microfluidic system of the present embodiments can be used in many application, including without limitation, genetic applications, chemical applications, biochemical applications, pharmaceutical applications, biomedical applications, chromatography applications, integrated circuit cooling, ink-jet printing, medical applications, radiological applications and environmental applications.

For medical applications, the microfluidic system of the present embodiments is suitable for diagnostic and patient management. For environmental applications the microfluidic system of the present embodiments is suitable for detecting hazardous materials or conditions such as air or water pollutants, chemical agents, biological organisms or radiological conditions. For genetic and biochemical applications the microfluidic system of the present embodiments is suitable for testing and/or analysis of DNA, and other macro or smaller molecules, or reactions between such molecules in an approach known as “lab-on-chip.”

The microfluidic system of the present embodiments can be used to obtain a variety of measurements including, without limitation, molecular diffusion coefficients, fluid viscosity, pH, chemical binding coefficients and enzyme reaction kinetics. Other uses for the microfluidic system of the present embodiments include, without limitation, immunoassays, flow cytometry, sample injection of proteins for analysis via mass spectrometry, sample injection of air or water samples for analysis via flamespectrometry, polymerase chain reaction (PCR) amplification, cell manipulation, cell separation, cell patterning and chemical gradient formation. Many of these applications have utility for basic research and clinical diagnostics.

The microfluidic system of the present embodiments can be integrated in microchips, such as DNA chips, protein chips and total analysis systems. For example, the microfluidic system of the present embodiments can be integrated in a DNA chip which includes a substrate for which probes with known identity are used to determine complementary binding, thus allowing massive parallel gene expression and gene discovery studies. The use of the microfluidic system of the present embodiments with such microchip can facilitate the production of small and high-density spots on the substrate. Since only a small amount of solution is needed to make one chip, the cost of chip production is substantially reduced. In addition, the microfluidic system of the present embodiments can create spots in consistent quantities and with uniform shape and size, so as to allow highly accurate comparisons between spots.

The microfluidic system of the present embodiments can also be used for sorting objects, such as cells. The microfluidic system of the present embodiments provide very high sorting rates, typically, but not obligatorily, from thousands to several tens of thousands of cells per second, using simple and inexpensive and optionally disposable components and materials.

The microfluidic system of the present embodiments can also be used in the area of biochemical and biophysical investigations of single cells. For example, the microfluidic system can isolate a cell or a group of cells of a certain type. Once the cell or group of cells is isolated, it can be accurately analyzed by various means, including, without limitation, optical, electrical, chemical and biological means.

The microfluidic system of the present embodiments can include a network of microchannels for transporting hundreds or thousands of cells or capsules and directing each cell or capsule to a predetermined location where a certain test is performed. This can be achieved in a continuous flow scheme, namely without generation of droplets. For example, the network can be constructed to allow divergent streamlines and the actuator or actuator(s) can control the flow in high temporal and/or spatial resolution (e.g., microsecond or sub-microsecond resolution in the time domain, and nanometer resolution in the spatial domain). The high resolutions allow rapid manipulation of very small volumes of fluid on a chip thereby facilitating manipulation of a single cell. Thus, each cell may be treated individually and based on the result of the test directed to a second location on the chip and so forth. A representative example of a network of microchannels and its application in accordance with some embodiments of the present invention is provided hereinunder.

The detection and/or separation can be done, for example, by means of the fluorescent emission, a technology known as fluorescence-activated cell sorting (FACS). For example, a sufficiently sensitive CCD sensor can be used in combination with an objective lens. The field-of-view under a 10× magnification can be approximately 400×400 μm. Thus, each image can contain approximately 1000 cells. At a frame rate of 50 frames per second the system of the present embodiments can analyze about 50,000 cells per second. Other imaging parameters (magnification, field-of-view, frame rate) are not excluded from the scope of the present invention.

In some embodiments, the microfluidic system is used for sorting and/or isolating circulating tumor cells (CTCs). One of the most devastating aspects of cancer is the propensity of cells from malignant neoplasms to disseminate from their primary site to distant organs and develop into metastases. Despite advances in surgical treatment of primary neoplasms and aggressive therapies, many cancer patients die as a result of metastatic disease.

Thus, the detection of occult cancer cells in circulation is important in assessing the level of tumor progression and metastasis. Because subclinical metastasis can remain dormant for many years, monitoring of patients' blood for circulating tumor cells (CTCs) may prove advantageous in detecting tumor progression before metastasis to other organs occurs. Assessment of circulating tumor cells also would provide a rapid monitoring system to determine if a specific therapy is effective. Isolating the CTC and testing the effect of different drugs on these cells may be highly beneficial. Heretofore, cytometers were used to detect CTCs but these techniques were not capable of isolate the CTCs or provide morphologic information on the cells.

However, the CTCs may be found in cancer patients in very low concentrations, typically 1 such cell in 1 ml of blood (approximately 1 CTC per billion erythrocytes), and current technologies lack the ability to scan a sufficiently large number of cells and detect the CTCs at sufficient certainty. Some filtration schemes have been used, but they rely only on the difference in sizes between the cells which is not selective enough. Heretofore, when CTCs are not present in the blood of a patient having a tumor, it is impossible to determine whether this is because the cells were not released from the tumor or because they cannot be detected using present technology.

The present inventors have uncovered the sorting technique of the present embodiments which can be used for sorting and isolating CTCs. In some embodiments, the technique can be used for isolating a single CTC. Once a CTC is detected (e.g., by optical means) it can be directed by the microfluidic system of the present embodiments to a separate container at a fast response time, typically less than 1 ms.

The CTCs appear in the blood before any clinical signs or symptoms are present. It is appreciated that separation and detection of CTCs may enable early cancer diagnosis and treatment. Additionally, isolating CTCs from a patient blood sample is highly beneficial since it allows customizing the treatment to the specific patient. Thus, the present embodiments can be used as part of a routine physical exam, in which a technician screens the patient's blood for any cancer lurking in his body. Using a small amount of the patient's blood, the physician can determine the best therapy to treat the patient's particular form of cancer.

The microfluidic system of the present embodiments can also be used in conjugation with other cell analysis techniques. For example, knowledge of cell activity can be achieved by measuring and recording electrical potential changes occurring within a cell, which changes depend on the type of cells, age of the culture and external conditions such as temperature or chemical environment. Thus, precisely controlling the physical and chemical environment of a cell under study significantly enhances the value of the research. Intracellular and extracellular electrical measurements have application in research studies of nerve cell bodies and tissue culture cells such as smooth muscle, cardiac, and skeletal muscle cells.

The microfluidic system of the present embodiments can also be used for producing microfluidic jets. Such microfluidic jets are useful in a variety of different applications, e.g., cutting tissue, introducing fluid into a cell and the like. Microfluidic jets can also be used for preparing emulsions. For example, the microfluidic system can jet an agent and one fluid medium into another fluid medium which may serve as the continuous phase of the emulsion. The agent can be a bioactive agent such that a bioactive agent-containing emulsion is formed by the jetting process.

A “bioactive agent,” as used herein, includes organic and inorganic drugs, as well as other agents such as proteins and peptides, that are biologically active when introduced to a biological system. Bioactive agent includes at least therapeutics and diagnostics which means any therapeutic or diagnostic agent now known or hereinafter discovered that can be jetted as described herein.

Once prepared, the emulsion can then be delivered to a biological system. The emulsion can be prepared “on-site,” namely it can be prepared in a close proximity to a patient or other biological system, just prior to the delivery. The advantage of using such emulsion is that droplets of low solubility drugs can be made to be very small and therefore, can exhibit increased bioavailability and may demonstrate decreased toxicity. With certain types of emulsions, lymphatic absorption can also be effectuated. Further, prolonged emulsion stability is not required since the emulsion can be used soon after preparation or even delivered directly to the patient tissue which, in turn, allows reduction of the amount of surfactant required, if desired.

Microfluidic jets can also be used for object encapsulation, e.g., the encapsulation of biologically active compounds (e.g., enzymes, antibodies) in lipid vesicles. Such encapsulations can be useful as chemical microreactors or as delivery vehicles for pharmaceuticals. The microfluidic system of the present embodiments can form encapsulations while independently controlling many parameters, including, without limitation, the membrane unilamellarity, the size of the vesicle, and the internal solution concentration.

The microfluidic system of the present embodiments is capable of encapsulating cells in nano- and even pico-liter capsules. The microfluidic system of the present embodiments can combine several droplet or capsule sources and optionally synchronize between these sources. Such synchronization can be used, for example, for coalescing droplets or capsules, e.g., for the purpose of single cell analysis and/or chemical analysis. For example, a droplet encapsulating a cell can merge with a droplet carrying a biologically active compound such as a lysis buffer. The resulting capsule preserves the product of the reaction even if it is a spilt content of a cell or proteins excreted by the cell. The capsule can be individually detected, e.g., while flowing under a sensor. The capsule can also be analyzed by merging to another droplet encapsulating a marker such as immunofluorescent marker.

In some embodiments of the present invention the microfluidic system is used in high performance liquid chromatography (HPLC). HPLC is a separation technique which is particularly useful when the partition coefficients of the components (compounds) are similar. In this technique, the sample is entrained in a mobile phase, continuously flowing from one end of a microchannel to the other. The sample is allowed to interact with a stationary phase bed present in the microchannel in the form of a matrix or beads. As the mobile phase passes through the microchannel, the compounds of the sample equilibrate between the mobile and stationary phases. Depending on the nature of the mobile phase, stationary phase and the components to be partitioned, the interacting time with the stationary phase vary from one component to the other, so that different compounds spend different fractions of time in the microchannel, before arriving to its opposite end. This allows the various compounds in the sample to be physically separated along the microchannel. A detection device can then detect the components when they elute from the microchannel and measures the time spent in the microchannel. Based on this time and the characteristics of the pulse generated by the detection device, the components are identified. The different components may also be individually collected.

Reference is now made to FIGS. 2A and 2B which are schematic illustrations of a top view of system 10 in embodiments in which the system comprises a plurality of microchannels. FIGS. 2A and 2B are representative examples of cross-junction configuration (FIG. 2A) and T-junction configuration (FIG. 2B). Other configurations are not excluded from the scope of the present invention. In the present embodiments, system 10 comprises at least one additional microchannel 28 being in fluid communication with microchannel 12. In some embodiments of the present invention system 10 comprises at least one additional fluid inlet 30 through which a fluid medium 32 is introduced to microchannel 28. Fluid medium 32 can be the same or different from fluid medium 18, as desired. In some embodiments of the present invention fluid media 18 and 32 are mutually immiscible. For example, fluid medium 18 can be an aqueous liquid and fluid medium 32 can be an oily liquid. For clarity of presentation, fluid media 18 and 32 are only shown (as block arrows) at FIG. 2B, but the skilled artisan would know how to add the fluids also to FIG. 2A.

The use of two immiscible fluids is particularly useful when system 10 serves as a microfluidic droplet system, in which case fluid 18 is the dispersed phase fluid and fluid 32 is the continuous phase fluid. In these embodiments, the actuator is controlled (e.g., by means of controller 24) so as to form droplets of fluid 18 in fluid 32. The use of two immiscible fluids is also useful when system 10 serves for encapsulations. In these embodiments, the actuator is controlled (e.g., by means of controller 24) so as to encapsulate objects flowing with fluid 18 within fluid 32.

Microchannel 28 can intersect with microchannel 12 or it can be branched from microchannel 28. In various exemplary embodiments of the invention microchannel 12 has a cross section which is down tapered (not shown, see FIG. 8 in the Examples section that follows) to form a nozzle at or near the connection between microchannel 12 and microchannel 28. In the representative example illustrated in FIG 2.2A and 2B, actuator 20 applies the pressure on the elastic wall of microchannel 12, and the other microchannels are not applied with external pressure. However, this need not necessarily be the case, since, for some applications, it may be desired to apply external pressure on more than one microchannel. In these embodiments, system 10 may comprise more than one actuator, e.g., one actuator for each microchannel to which external pressure is to be selectively applied.

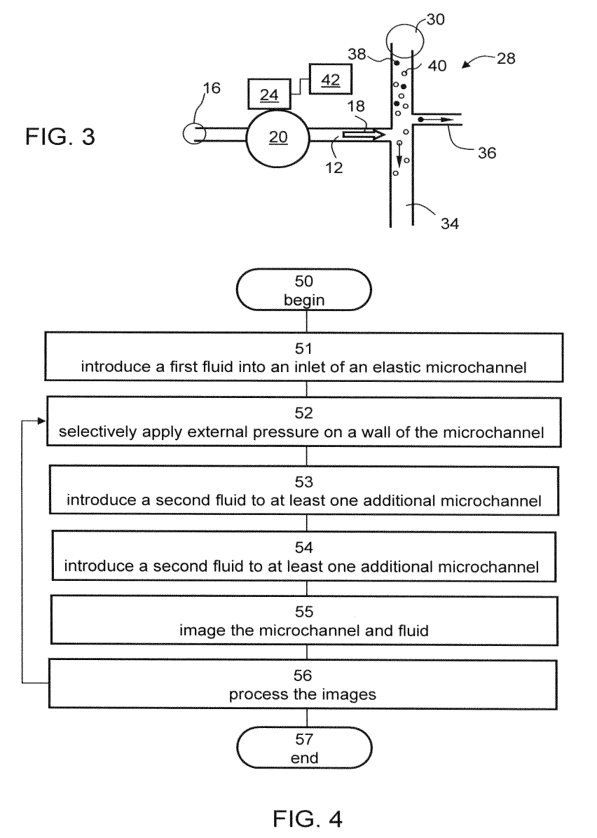

Reference is now made to FIG. 3 which is a schematic illustration of a top view of system 10 in embodiments in which the system is used for sorting or isolation of objects. In the representative illustration, microchannel 28 comprises a main microchannel 34 and a branch microchannel 36, and microchannel 12 branches from main microchannel 34 generally opposite to branch microchannel 36 but offset with respect thereto.

Application of pressure on microchannel 12 (by actuator 20) results in increased fluid flow in branch microchannel 36. Such configuration can be used for sorting objects flowing with the fluid in main microchannel 34. For example, suppose that two types of objects 38 and 40 are flowing in microchannel 34. These types are represented in FIG. 3 by solid circles and empty circles, respectively. Suppose further that it is desired to isolate objects 38. According to various exemplary embodiments of the present invention, actuator 20 applies external pressure on microchannel 12 whenever object 38 passes over branch microchannel 36. The increase in pressure within microchannel 12 causes a change of the flow in microchannel 34 such that object 38 is forced to enter branch microchannel 36. In various exemplary embodiments of the invention the resistance to flow characterizing main microchannel 34 is lower than the resistance to flow characterizing branch microchannel 36. This ensures that when actuator 20 does not apply the external pressure the primary flow is along main microchannel 34. Several sorting configurations similar to the configuration shown in FIG. 3 can be connected in a series so as to allow sorting of several types of different cells.

In various exemplary embodiments of the invention system 10 further comprises an imaging system 42 which is configured for imaging the microchannel(s) and the fluid(s). Controller 24 can be configured for processing images generated by imaging system 42 and activating and deactivating actuator based on, and synchronously with, the processing. For example, when system 10 is used for isolating objects, controller 24 can process the images and signal actuator 20 to apply pressure on the elastic wall of microchannel 12 which the object to be sorted passes at the entry of branch microchannel 36.

In various exemplary embodiments of the invention a focusing procedure is employed for focusing the flow of objects in a predetermined focus region of the microchannel. This embodiment is particularly useful when system 10 is used for sorting or separating of objects.

The focus region is preferably along the central line of the microchannel. Focusing along the center line, may be advantageous over focusing in other areas of the microchannel in several aspects. For example, at the center of the microchannel the flow speed is higher than off-center. Therefore, objects focused along the center line flow faster, and may be handled in higher throughputs. Additionally, the objects oftentimes tend to diffuse perpendicularly to the flow direction and the transverse diffusivity is enhanced by the shear (an effect known as Taylor dispersion). This tendency is minimal at the center of the microchannel where the shear-rate is minimal, and therefore, faster movement of the objects along the flow direction can be achieved with minimal sample width broadening due the transverse shear-augmented diffusion. Furthermore, focusing the objects along the center line minimizes their interactions with the wall of the channel and decreases adsorption/adhesion phenomena.

The focusing can be in any dimension. In some embodiments, the focusing is horizontal, that is, the objects are focused at a horizontal region of limited depth, preferably near half the depth of the microchannel; in some embodiments, the focusing is in a vertical direction, that is, the objects concentrate in a focusing region that is perpendicular to the microchannel's bottom, e.g., at about half the width of the microchannel; and in some embodiments, a two-dimensional focusing is employed, in the sense that the objects flow away of the bottom and top wall of the microchannel and also away of the walls of the microchannel, and concentrate in a volume that does not extend to touch any of the microchannel's walls.

Horizontal and two-dimensional focusing may be advantageous, for example, when the objects are to be analyzed optically, with an optical device positioned above the microchannel. In such cases, the horizontal focusing may bring all the objects to be within the focus of the optical analyzer, allowing for faster analysis of the objects than would be allowed if the objects are focused vertically.

The focusing is preferably done such that the focused objects are lined up, optionally one by one, such that the centers of a substantial portion of the objects (e.g., at least 90%, more preferably at least 95%, more preferably at least 99%) is within a cylinder having a radius that is about the same as a typical radius of the objects. Such focusing considerably reduces the longitudinal dispersion of the objects and yields higher throughputs.

Any focusing procedure known in the art can be employed. For example, in some embodiments, the focusing is effected by the technique disclosed in International Patent Publication No. WO2008/149365, the contents of which are hereby incorporated by reference. In this technique, the objects are suspended in a suspending medium having such viscoelastic properties (e.g., viscosity, elasticity, shear thinning) that when it flows in the microchannel it increases the concentration of the objects in a focus region inside the microchannel.

The viscoelastic properties of the suspending medium can be controlled, for example, by adding to the suspending medium a modifier which modifies the viscoelastic properties of the suspension. Optionally, the modifier is a high molecular weight polymer, for example, a polymer having molecular weight of between about 50 and about 1000 kilo-Daltons. Preferably, the modifier is added in amounts that are soluble in the dispersing medium. Optionally, but not necessarily, the modifier is bio-compatible. This embodiment is particularly useful when the objects comprise biological material, such as living cells. Representative examples of modifiers suitable for the embodiments include, without limitation, polyacrylamide (PAA) polyethyleneglycol (PEG), polysucrose (Ficoll™), polyglucose (Dextran), methylcellulose and xanthan gum.

In some embodiments of the present invention, the suspending medium has the same density everywhere inside the microchannel. Thus, in these embodiments, the focusing is without a density gradient.

Also contemplated are other focusing techniques. A representative example includes, without limitation, sheath-flow focusing (also known as hydrodynamic focusing). Sheath flow is a type of laminar flow in which one layer is surrounded by another layer on more than one side. In some embodiments, the sheath-flow is characterized by concentric layers of fluids, whereby one layer is completely surrounded on all sides by another layer. Sheath-flow focusing technique suitable for the present embodiments is disclosed in U.S. Pat. Nos. 5,858,187, 6,120,666, 6,159,739 and 6,506,609 the contents of which are hereby incorporated by reference.

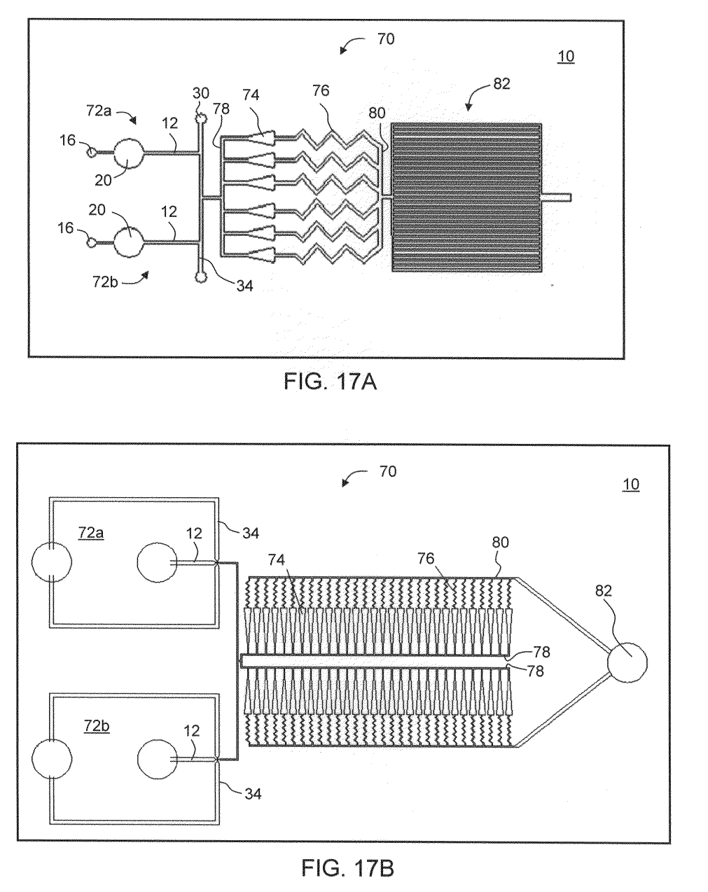

Reference is now made to FIGS. 17A and 17B which are schematic illustrations of top views of system 10 in embodiments in which a network of microchannels is employed for multiple coalescence. These embodiments can be used, for example, for single cell analysis or other applications in which coalescence can be utilized.

In the present embodiments, system 10 comprises a microfluidic network 70 which can include two or more microfluidic droplet generators 72. Two such droplet generators 72a and 72b are shown in the representative example illustrated in FIGS. 17A and 17B, but this is not intended to limit the scope of the picture-element to any number of droplet generators. In some embodiments of the present invention one or more of the droplet generators is actuated by a piezoelectric actuator 20, as further detailed hereinabove.

The microfluidic droplet generators generate droplets, preferably at kilohertz or megahertz rates. In the representative example illustrated in FIGS. 17A and 17B, a cross-junction configuration is employed, wherein, for each module, a segmented phase flows in a first microchannel (e.g., microchannel 12) and a continuous phase flows in a second microchannel (e.g., microchannel 34) crossing the first microchannel. However, this need not necessarily be the case, since, for some applications, it may not be necessary for the droplet generators to have a cross-junction configuration. For example, one or more of the droplet generators (e.g., all the droplet generators) can have a T-junction configuration.

The droplets generated by the microfluidic droplet generators can be, for example, about 20 μm in diameter, but other droplet sizes are also contemplated. Generally, the size of and rate of droplets is determined by the geometry and ratio of the continuous phase flow rate to the segmented phase flow rate, and by the operation scheme of the actuator (in embodiments in which an actuator is employed). In some embodiments of the present invention, one or more of the droplet generators carries a suspension of cells and the other droplet generator(s) carry other suspension(s) which may comprise, e.g., a reagent, a drug, an antigen or the like.

Network 70 can comprise one or more droplet merging chambers 74 which are configured to impose a velocity gradient on the flow. In various exemplary embodiments of the invention chamber 74 is tapered or circular and the velocity gradient is imposed due to the increase in cross sectional area of the chambers. The velocity gradient forces following droplets to collide within chamber 74 and coalescent to a larger droplet. In various exemplary embodiments of the invention the droplet generators are operated synchronously such that droplets generated by one generator coalescent at the merging chamber with droplets generated by another generator. For example, droplets of a cell suspension can coalescent with droplets of reagent suspension.

In some embodiments of the present invention network 70 comprises one or more mixing chambers 76 which enhance mixing inside the droplets by creating counter rotating vortices in case the mixing through diffusion is insufficient. Mixing chamber 76 can have any shape with several opposite curvatures such as a zigzag shape and the like.

Network 70 can have any number (e.g., at least 5 or at least 10 or at least 20 or at least 30 or at least 40 or at least 50) of droplet merging chambers and mixing chamber. Preferably, each droplet merging chamber is connected to one mixing chamber. The droplet merging chambers are preferably breached from one or more main channels 78 (e.g., in a comb-like arrangement) which is in fluid communication with the droplet generators 72. In use, channel 78 is fed from droplets from the generators and distributes the droplets among the droplet merging chambers. From the droplet merging chambers, the merged droplets continue to flow to the mixing chambers. In the schematic illustration of FIG. 17A network 70 comprises 6 droplet merging chambers and 6 mixing chamber, and in the schematic illustration of FIG. 17B network 70 comprises 60 droplet merging chambers and 60 mixing chamber. Large number of chambers is advantageous since coalescence is a time dependant process. In a typical rate of 1000 droplets/second, for example, no coalescence may occur as two droplets require a minimal contact duration before merging. Thus, slowing the flow and parallel droplet merging is advantageous.

In various exemplary embodiments of the invention network 70 comprises one or more collection microchannels 80, which can be in fluid communication with an inspection zone 82. In use, the droplets from droplet merging chambers 74 and optionally mixing chambers 76, are collected by collection microchannels 80 and transferred to inspection zone 80, at which the droplets can be analyzed by various means, including, without limitation, optical, electrical, chemical and biological means. Inspection zone 80 can also be in a form of a comb-like arrangement of microchannels (see FIG. 17A), in which the droplets can be further slowed so as to allow more accurate inspection. This embodiment is particularly useful when the inspection is by means of fluorescent emission, since slowly moving droplets can be detected via relatively long exposure time of an optical detector.

Reference is now made to FIG. 4 which is a flowchart diagram of a method according to various exemplary embodiments of the present invention. It is to be understood that, unless otherwise defined, the operations described hereinbelow can be executed either contemporaneously or sequentially in many combinations or orders of execution. Specifically, the ordering of the flowchart diagrams is not to be considered as limiting. For example, two or more operations, appearing in the following description or in the flowchart diagrams in a particular order, can be executed in a different order (e.g., a reverse order) or substantially contemporaneously. Additionally, several operations described below are optional and may not be executed.

The method begins at 50 and continues to 51 at which a first fluid (e.g., fluid 18) is introduced into an inlet (e.g., inlet 16) of an elastic microchannel (e.g., microchannel 12). At 52 the method selectively applies external pressure on the wall of the microchannel so as to control the flow of the first fluid in the microchannel. The external pressure can be applied via a flexible membrane (e.g., membrane 16) adjacent to the elastic wall. In various exemplary embodiments of the invention the method continues to 53 at which a second fluid (e.g., fluid 32) is introduced to one or more additional microchannels, as further detailed hereinabove. Optionally and preferably the method continues to 55 at which the microchannel and fluid are imaged, and 56 at which the images are processed. The method can loop back to 52 and apply the pressure is based on, and synchronously with, the processing of the images, as further detailed hereinabove.

The method ends at 57.

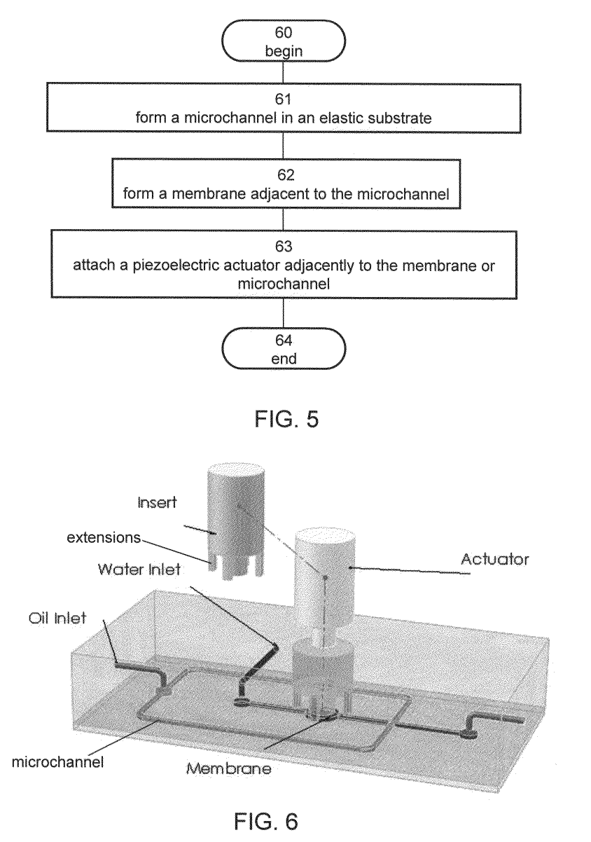

Reference is now made to FIG. 5 which is a flowchart diagram of a method suitable for manufacturing a microfluidic system according to various exemplary embodiments of the present invention.

The method begins at 60 and continues to 61 at which an elastic microchannel is formed in a substrate. The formation can be done by any technique known in the art, including, without limitation, soft lithography, hot embossing, stereolithography, three-dimensional jet printing, dry etching and injection molding. Preferably, the process also comprises formation of a recess or the like for facilitating the positioning of the actuator. A representative example of a soft lithography process is provided in the Examples section that follows.

The substrate can be an elastomeric polymer substrate. Suitable elastomeric polymer substrate materials are generally selected based upon their compatibility with the manufacturing process (soft lithography, stereolithography and three-dimensional jet printing, etc.) and the conditions present in the particular operation to be performed by the microfluidic system. Such conditions can include extremes of pH, pressure within the microchannels, temperature, ionic concentration, and the like. Additionally, elastomeric polymer substrate materials are also selected for their inertness to critical components of an analysis or synthesis to be carried out by the system. Elastomeric polymer substrate materials can also be coated with suitable materials, as discussed in detail below.

When the microfluidic system includes an optical or visual detection element, the elastomeric polymer substrate material is preferably transparent to allow, or at least facilitate the detection. Alternatively, transparent windows of, e.g., glass or quartz, may be incorporated into the system for these types of detection elements. The elastomeric polymer can have linear or branched backbones, and can be crosslinked or non-crosslinked.

Given the tremendous diversity of polymer chemistries, precursors, synthetic methods, reaction conditions, and potential additives, there is a large number of possible elastomer systems that are contemplated for fabricating the microfluidic system of the present embodiments.

Representative examples elastomeric polymers include, without limitation, polydimethylsiloxane (PDMS), polyisoprene, polybutadiene, polychloroprene, polyisobutylene, poly(styrene-butadiene-styrene), polyurethanes and silicones. Since the stroke of the piezoelectric actuator is small (nanometer range), the present Inventors also contemplate the use of polymers which are generally non-elastomeric, provided that the wall of the formed microchannel is sufficiently elastic, as further detailed hereinabove. Representative examples of such polymers include, without limitation, PMMA and polycarbonate.

The method optionally continues to 62 at which a membrane is formed adjacently to the elastic wall of the microchannel. The membrane can be formed by any suitable technique known in the art. For example, when a soft lithography technique is employed, a rigid insert can be utilized for defining the membrane. Following curing of the elastomeric polymer, the insert can be removed, e.g., by pulling technique.

The method continues to 63 at which a piezoelectric actuator is attached adjacently to the microchannel or membrane (in embodiments in which the membrane is formed), such as to allow the actuator to apply external pressure on the elastic wall of the microchannel. The piezoelectric actuator can be glued to a recess formed in the elastic substrate.

The method ends at 64.

The system and method of the present embodiments can be used for manipulating (e.g., maneuvering, separating, sorting, forming droplets, bubbles or encapsulations) many types of fluid media and objects present in fluid media. The objects can comprise organic, inorganic, biological, polymeric or any other material. For example, the fluid medium can comprise blood product, either whole blood or blood component, in which case the objects can be erythrocytes, leukocytes, platelets and the like. The fluid medium can also comprise other body fluids, including, without limitation, saliva, cerebral spinal fluid, urine and the like. Also contemplated are various buffers and solutions, such as, but not limited to, nucleic acid solutions, protein solutions, peptide solutions, antibody solutions and the like.

Objects in the fluid medium can comprise other materials, such as, but not limited to, cells, bacteria, cell organelles, platelets, macromolecules, vesicles, microbeads, covered with antibodies specific to soluble factors such as ligands, shaded receptors and biological materials containing a fatty tissue or a microorganism. The objects which are manipulated by the system and method of the present embodiments can also be made of or comprise synthetic (polymeric or non-polymeric) material, such as latex, silicon polyamide and the like. The object can be optically visible or transparent. The objects can also emit light or be conjugated to other objects to facilitate their detection.

It is expected that during the life of this patent many relevant particles and fluids will be developed or found and the scope of the terms particles, particles manipulation, particles separation and particles sorting is intended to include all such new technologies a priori.

As used herein the term “about” refers to +10%.

The word “exemplary” is used herein to mean “serving as an example, instance or illustration.” Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments.” Any particular embodiment of the invention may include a plurality of “optional” features unless such features conflict.

The terms “comprises”, “comprising”, “includes”, “including”, “having” and their conjugates mean “including but not limited to”.

The term “consisting of means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### EXAMPLES

Reference is now made to the following examples, which together with the above descriptions illustrate some embodiments of the invention in a non limiting fashion.

### Example 1

### Prototype Microfluidic Systems

Prototype microfluidic systems, about 50 μm in height were manufactured according to the teachings of some embodiments of the present invention.

The prototype microfluidic systems were fabricated in PDMS by soft lithography. The production procedure is illustrated in FIG. 6.

A silicon wafer was cleaned, spun coated with SU-8 negative photoresist, soft baked, exposed to UV light through a transparency film mask and baked again. Development resulted in a master mold containing the microchannel network pattern in relief. The master was used as a bottom mold. After silanization with trimethylchlorosilane (Sigma Aldrich) the master was pressed against a Teflon mold.

A custom-made metal cylinder with four 1×1 mm extensions was placed on the mold above one of the microchannels to define a PDMS membrane. The length of the four extensions determines the width of the membrane. After PDMS degassing and curing, the cylindrical insert was pulled out of the PDMS defining a recess for the actuator.

A glass slide, 76×50×mm (Marienfeld, Germany) was spin coated. The PDMS slab was peeled off the mold and bonded to the glass slide. Bonding was achieved using oxygen plasma activation and ensured sealing of the microfluidic system from below.

A small (3 mm length, 3 mm diameter) stainless steel rod was glued to a piezoelectric actuator stack (Max displacement 17.4 μm, Thorlabs USA), and was fitted into the recess. The rod served for conducting the displacements of the actuator to the PDMS membrane and also prevented the membrane from buckling.

Prototype microfluidic systems were fabricated in a T-junction geometry and cross-junction geometry, having orifice width to main channel width ratios of 1/2 and 1.

### Example 2

### Droplet Generation

The prototype microfluidic systems described in Example 1 were used for generation of water droplets in oil.

### Methods

A custom made aluminum frame was constructed in order to hold the prototype systems on the microscope. The piezoelectric actuator stack was fastened to a stainless steel arm which was bolted to the aluminum frame, so as to allow controlling the position and angle of the actuator.

The voltage signal applied to the actuator was generated using an MDT683A open loop piezo controller (Thorlabs, USA) which was modulated using a signal generator (3320A, Agilent USA). A scope (TDS 1002, Tektronix USA) was connected to the signal generator in order to monitor the output voltage.

Pressure driven flow was applied using gravity. Two containers, one filled with filtered oleic acid (Sigma, USA) and the other with DI water were positioned at a fixed height during the experiments. It was thus possible to instantly reach equilibrium between the water and oil pressure, stopping the water vertex just before the junction.

At this point the signal generator was started, generating pulses of different geometries, duration, amplitudes and frequencies.

A high speed CCD camera (CPL MS1000, Canadian Photonics Labs) was mounted on an upright microscope (80i, Nikon Japan) in order to record the droplets formation.

The films were analyzed using custom made image processing software. The software, implemented in Matlab (Matworks, USA), segmented the pictures and calculated the diameter and velocity of the droplets.

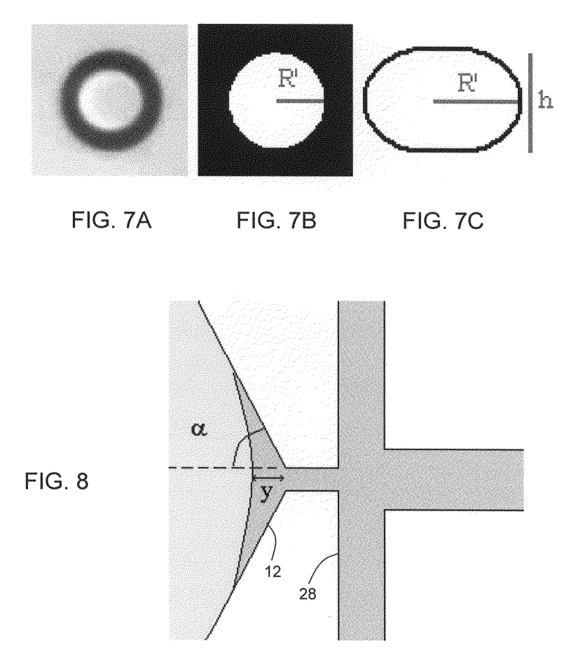

Assuming the droplets obtain a shape combined of a cylinder and a semi torus in the main channel, their volume was evaluated using the following equation (see also FIGS. 7A-C):

$$V = π {\int }_{- r}^{r} {( R + a )}^{2} d z , \qquad ( EQ . 1 )$$

where a=\sqrt{h²/2−z²}, h is the channel height, R=R′−h/2, and R′ is the radius of the droplets measured by image analysis. Results The oil and water reservoirs were fixed at a certain height inducing constant pressures at the inlets. After positioning the oil reservoir, the water reservoir could be positioned at a range of heights and still remain at a steady state. Thus the water vertex location was easily controlled by moving the water reservoir vertically and remained stable thereafter. At this point, the actuator was started pushing the water vertex into the junction. Hence, the droplet size depends on this initial position of the vertex as well as the voltage signal.

The equilibrium state which enabled this process is governed by hydrostatic pressure and interfacial tension as follows:

Pₒ−γ cos θ(1/y tan α+2/h)=P_{w}, (EQ. 2)

where P₀ and P_{w} are the oil and water pressures, respectively, γ is the water/oil surface tension, α is the nozzle slanting angle, θ is the contact angle, h is the height of the channel and y the vertex distance from the junction (see FIG. 8).

Thus, for a sufficiently large water pressure, the water vertex advances in the nozzle until it reaches a curvature radius which is balanced by the pressure drop over the interface. From this standpoint, a sharp decline in cross section of the nozzle is preferred. The reason is that as a decreases the dependence of water pressure on initial vertex position is also decreased thus ensuring high degree of repeatability in droplet size.

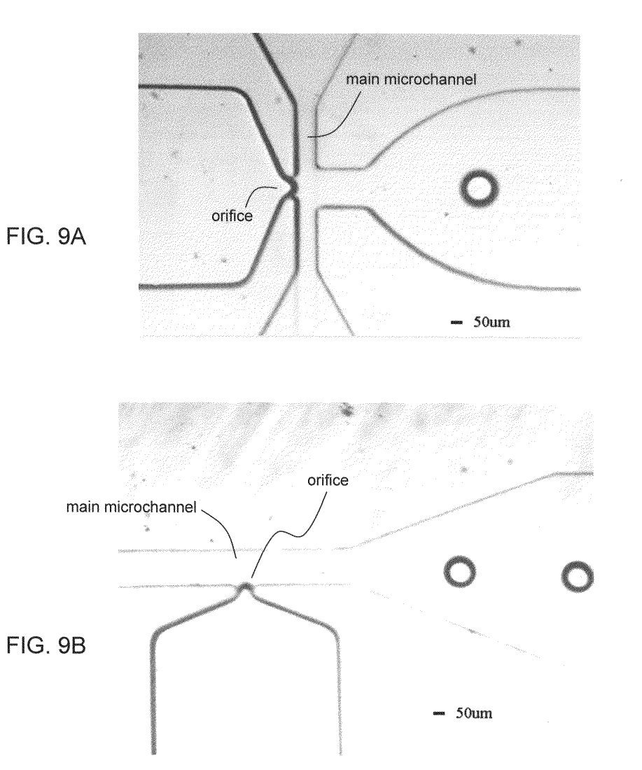

Four droplet generating geometries were examined using the piezoelectric actuation technique of the present embodiments. These included cross configuration, T configuration, each with an orifice width to main channel width ratios of 1/2 and 1. Microscope image of the cross configuration and T configurations for the 1/2 ratio are shown in FIGS. 9A and 9B, respectively.

It was found that both types of configurations were appropriate for droplet generation. As the geometric ratio decreased, the range of obtainable droplet size broadened. In configurations with a geometric ratio of 1, a high stroke volume resulted in droplets tending to break into two or more droplets upon reaching the junction. Thus in these configurations, as the stroke volume increased above a certain threshold, more droplets were generated by each pulse. Bursts of equally sized droplets were repeatedly produced using a constant stroke volume above this threshold. The configurations having a geometric ratio of 1/2 enabled a wider range of single droplet generation.

The reason for the different behavior is attributed to the higher droplets velocity obtained in a configuration having a narrower main channel. The capillary number increase with the velocity according to the formula Ca=ηu/σ, where η is the viscosity of the continuous fluid, u its velocity and σ the surface tension, hence the tendency to break. Furthermore, as the geometric ratio increases the jet instantly pushed by the actuator into the main channel reaches the Rayleigh-Plateau criterion earlier thus preventing single large droplets formation.

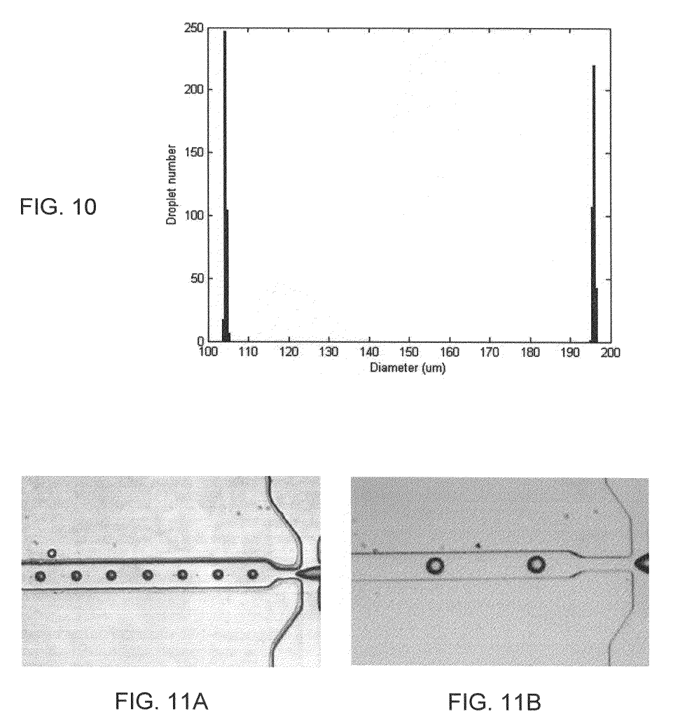

FIG. 10 shows two typical diameter distributions obtained by applying a rectangle voltage pulse of 20 ms with amplitudes of 90 V and 50 V respectively. The mean diameter values were 195.8 μm and 104.3 μm with standard deviations of 0.27 μm (0.13%) and 0.23 μm (0.22%) respectively. The high uniformity achieved using the technique of the present embodiments surpasses other methods such as drop break off, rupturing in complex fluids, crossflow emulsification, and hydrodynamic breakup. Two microscope images demonstrating the size and shape uniformity of the generated droplets are provided in FIGS. 11A and 11B.

Keeping the PDMS membrane thickness much smaller than its diameter maintains linear translation of the membrane while prevents or minimizing its bending. With such linear translation the stroke volume equals the actuator stroke times its cross section. In the linear domain of the piezoelectric actuator, the droplet volume is also a linear function of the applied voltage.

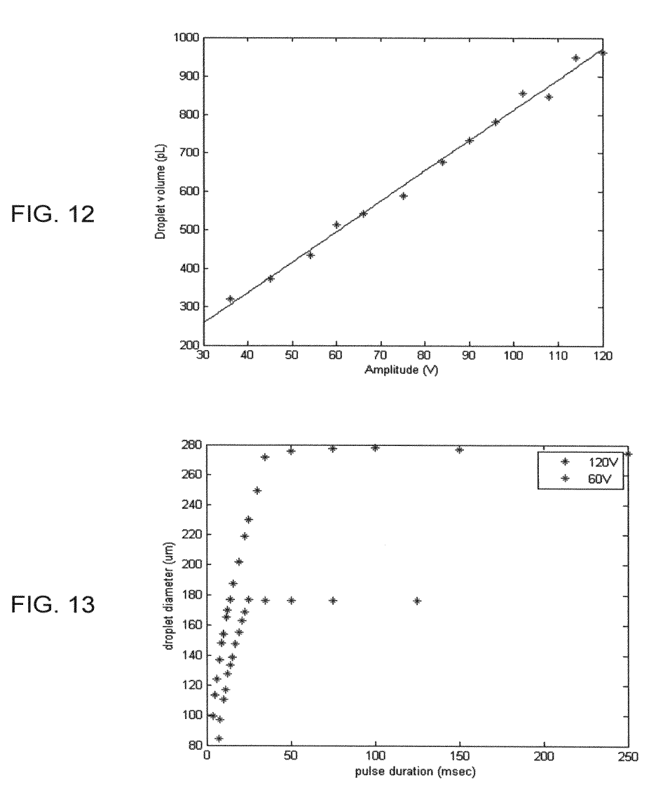

FIG. 12 shows the calculated mean droplet volume as a function of the applied voltage using a pulse of 15 ms, for the microfluidic system with the T-junction configuration. As shown, the droplet volume increases linearly with the pulse amplitude (R²=0.993).

The PDMS membrane resistance to bending is negligible compared to the hydrostatic pressure applied by the water. This may be confirmed by Timoshenko's formula for the maximum deflection of a circular clamped plate:

$$p = \frac{{w}_{max} {a}^{4}}{64 D} \qquad ( EQ . 3 )$$

where p is the load, D the flexural rigidity, a is the radius and wₘₐₓ the maximum translation of the actuator. Thus, as the pressures at work are two orders of magnitude larger than the pressure required to bend the membrane, its thickness and elasticity may be varied considerably without significantly changing the operation.

FIG. 13 is a graph showing the mean droplet diameter as a function of the pulse duration as obtained in the T-junction microfluidic system operated according to various exemplary embodiments of the present invention using voltage amplitudes of 60 V and 120 V. As shown, the droplet size increases rapidly with increasing pulse duration until a critical value is reached whereupon it remains constant irrespectively of any further prolonging of the pulse.

There is a distinction between two modes of droplet formation which are dominated by different physical mechanisms. At the region below the critical pulse duration, the droplet size increases linearly with the pulse duration (R²=0.97). This may be explained as follows: the actuator pushes a certain volume of water through the inlet into the junction it then retracts instantly (as its reaction time is in the order of microseconds) and the membrane returns to its normal position pulling back some of the water. This reverse flow shears off the water vertex which is already surrounded by the oil flow. As the pulse duration increases, more water flows into the forming droplet and increases its volume before the back flow caused by the retracting membrane.

At some point, where the pulse duration reaches a critical value, the droplet detaches from the water vertex before the retraction of the membrane begins. In this case, the droplet is sheared by the continuous fluid flow only and its radius obeys the relation:

$$r = \frac{σ}{\hat{ɛ}} \qquad ( EQ . 3 )$$

where, \hat{ε} is the shear rate. The same behavior was noticed using the cross configuration.

The present inventors found that the microfluidic system of the present embodiments can be operated to obtain droplets in a range of diameters at two modes of droplet formation. In a first mode, short pulses (e.g., below 20 ms) are employed and the droplet size linearly correlates with the actuator voltage. In a second mode very long pulses (e.g., above 30 ms) are employed resulting in droplet size which is independent on actuator voltage but depends on flow rate, geometry and actuator configuration. The possible rate of droplet formation in the second mode is lower than the first mode due to the longer pulses.

### Example 3

### Sorting

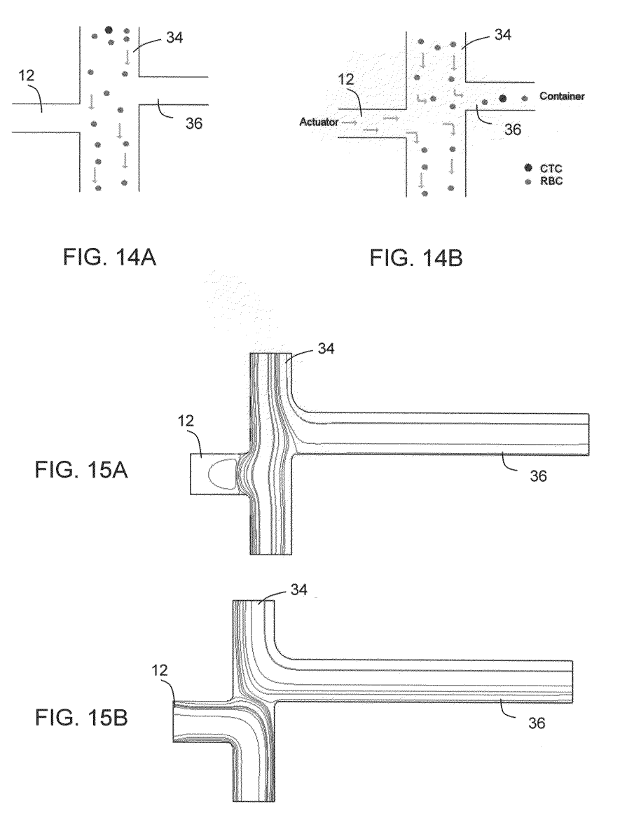

A prototype microfluidic system was manufactured as described in Example 1 and used for sorting objects, such as, but not limited to, particles and cells. The microchannel configuration and sorting procedure are schematically illustrated in FIGS. 14A and 14B.

The prototype microfluidic system included a main microchannel 34, and two branch microchannels 12 and 36. The actuator (not shown, see FIG. 6) was mounted above microchannel 12, and was configured to apply external pressure on the elastic wall thereof. The resistance to flow characterizing main microchannel 34 was lower than the resistances to flow characterizing branch microchannels 12 and 36.

The prototype system also included CCD camera (not shown, see, e.g., imaging system 42 in FIG. 3) and a controller (not shown see, e.g., 24) which was configured for processing the images of the CCD camera and activating and deactivating the actuator based on the processing.

In FIG. 14A, a suspension of red blood cells (RDC) flows undisturbed in the main channel 34. Once the actuator is activated to apply external pressure on microchannel 12 (FIG. 14B) the diverging streamlines carry the CTC and a few red blood cells to branch microchannel 36 and into a container.

FIGS. 15A and 15B show the results of a finite element simulation (COMSOL Multiphysics®) directed to the investigation of flow within the microchannels before (FIG. 15A) and after (FIG. 15B) application of external pressure on microchannel 12. FIGS. 15A and 15B show streamlines within microchannels 12, 34 and 36. The amount of streamline in a represents the amount of flow in the respective microchannel. As shown in FIG. 15A, before application of external pressure on microchannel 12, most of the streamlines pass through the lower resistivity (microchannel 34). The suspended objects (cells, particles, etc.) follow theses stream lines substantially without entering the braches.

Once the external pressure is applied to microchannel 12 (FIG. 15B), the fluid is pushed from microchannel 12 into the main microchannel, resulting in development of a substantially steady flow. The constant flow rate from microchannel 12 bends the main streamlines into branch microchannel 36 such that the object at the entry of microchannel 36 enters microchannel 36.

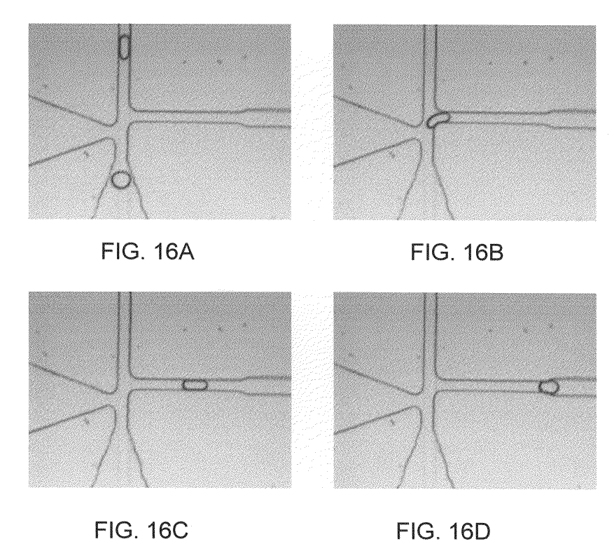

FIGS. 16A-D are images acquired by the CCS camera in four stages of the sorting procedure. The droplets are generated at the top and are flowing downwards towards the vertical branch as it has the smallest resistance. When the actuator infuses additional oil from the left microchannel branch the stream-lines coming from the upper branch turn into the right branch carrying the droplet into the branch.

### Example 4

### Coalescence of Droplets

The ability of the present embodiments to generate on demand droplets allows synchronization between different droplet sources. Such synchronization can be used, for example, for coalescing droplets, e.g., for the purpose of single cell analysis and/or chemical analysis.

A prototype microfluidic system was manufactured according to various exemplary embodiments of the present invention and was used for coalescing droplets. The prototype system included two microfluidic droplet generators each having microchannels intersecting each other in a cross-junction configuration. The prototype system included a droplet merging chamber and a mixing chamber. A CCD camera was used for imaging the droplets in the cross-junctions, the droplet merging chamber and immixing chamber.

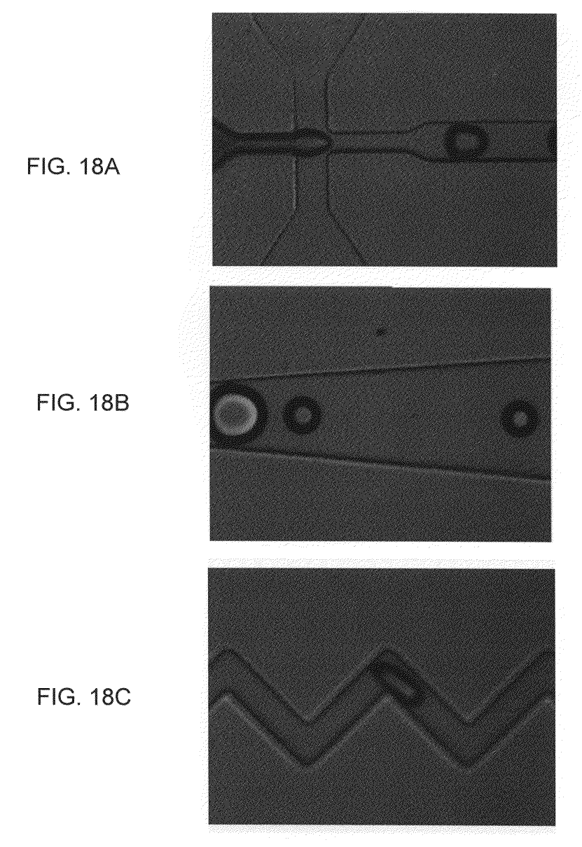

FIGS. 18A-C are images of the CCD camera as acquired during the procedure. FIG. 18A shows colored droplets formed at one of the cross-junctions, FIG. 18B shows coalescence of droplets to a larger droplet at the droplet merging chamber, and FIG. 18C shows the mixing chamber which creates mixing turbulences inside the droplets due to velocity gradients.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

What is claimed is:

1. A microfluidic system, comprising:
an elastic microchannel having an elastic wall and being in fluid communication with a fluid inlet configured for receiving a first fluid; and
a piezoelectric actuator configured for controlling flow of said first fluid in said microchannel by selectively applying external pressure on said elastic wall.

2. The system of claim 1, further comprising a controller configured for activating and deactivating said actuator.

3. The system of claim 1, further comprising a flexible membrane adjacent to said elastic wall, said membrane being constituted to transmit displacements induced by said actuator to said elastic wall.

4. The system of claim 1, further comprising at least one additional microchannel being in fluid communication with said elastic microchannel.

5. The system of claim 4, wherein said at least one additional microchannel comprises a main microchannel and a branch microchannel, and wherein said elastic microchannel branches from said main microchannel generally opposite to said branch microchannel but offset with respect thereto, such that application of said pressure on said elastic microchannel results in increased fluid flow in said branch microchannel.

6. The system of claim 5, wherein a resistance to flow characterizing said main microchannel is lower than a resistance to flow characterizing said branch microchannel.

7. The system of claim 2, further comprising:
an imaging system configured for imaging said microchannel and said fluid;
wherein said controller is configured for processing images generated by said imaging system and activating and deactivating said actuator based on, and synchronously with, said processing.

8. The system of claim 7, wherein said actuator is controlled so as to isolate or sort objects flowing with said first fluid.

9. The system of claim 4, wherein said at least one additional microchannel is configured for receiving a second fluid through a second inlet, said first and said second fluids being mutually immiscible, and wherein the system further comprises a controller configured for activating and deactivating said actuator.

10. The system of claim 9, wherein said actuator is controlled so as to form droplets of said first fluid in said second fluid or to encapsulate objects flowing with said first fluid within said second fluid.

11. The system of claim 2, wherein said actuator is controlled so as to produce a pulsed microfluidic jet.

12. A microfluidic system, comprising:
a first microfluidic droplet generator and a second microfluidic droplet generator configured for generating fluid droplets in a main microchannel being in fluid communication with said droplet generators; and
a plurality of droplet merging chambers branched from said main microchannel and configured to impose a velocity gradient on droplets flowing in said droplet merging chambers, such that at least two droplets collide and coalescent to a larger droplet within at least one of said droplet merging chambers.

13. The system of claim 12, further comprising a plurality of mixing chambers respectively connected to said droplet merging chambers and constituted for reducing the velocity of droplets exiting said droplet merging chambers and flowing within said mixing chambers.

14. The system of claim 12, wherein said droplet merging chambers branch from said main microchannel in a comb-like arrangement.

15. The system of claim 12, further comprising a collection microchannel in fluid communication with said droplet merging chambers, for collecting said larger droplets.

16. A method, comprising:
introducing a first fluid into an inlet of an elastic microchannel having an elastic wall, and
selectively applying external pressure on a wall of said microchannel so as to control the flow of said first fluid in said microchannel.

17. The method of claim 16, wherein said external pressure is applied via a flexible membrane adjacent to said elastic wall.

18. The method of claim 16, further comprising introducing a second fluid to at least one additional microchannel being in fluid communication with said elastic microchannel.

19. The method of claim 18, wherein said at least one additional microchannel comprises a main microchannel and a branch microchannel, wherein said elastic microchannel branches from said main microchannel generally opposite to said branch microchannel but offset with respect thereto, and wherein said application of said pressure is executed so as to increase fluid flow in said branch microchannel.

20. The method of claim 16, further comprising:
imaging said microchannel and said fluid; and
processing images generated by said imaging method;
wherein said application of pressure is based on, and synchronously with, said processing.

21. The method of claim 20, wherein said application of pressure is executed so as to isolate objects flowing with said first fluid.

22. The method of claim 20, wherein said application of pressure is executed so as to sort objects flowing with said first fluid.

23. The method of claim 18, wherein said application of pressure is executed so as to form droplets of said first fluid in said second fluid.

24. The method of claim 23, wherein a size dispersion of said droplets is characterized by a standard deviation of less than 1%.

25. The method of claim 18, wherein said application of pressure is executed so as to encapsulate objects flowing with said first fluid within said second fluid.

26. The method of claim 16, wherein said application of pressure is executed so as to produce a pulsed microfluidic jet.

27. A method of manufacturing a microfluidic system, comprising:
forming an elastic microchannel in a substrate; and
attaching a piezoelectric actuator adjacently to said microchannel such as to allow said actuator to apply external pressure on an elastic wall of said microchannel.

28. The method of claim 27, further comprising forming a membrane adjacently to said elastic wall, said membrane being constituted to transmit displacement induced by said actuator to said elastic wall.
